(19) United States
(12) Patent Application Publication
(10) Pub. No.: US 2010/0176484 A1
(43) Pub. Date: Jul. 15, 2010

(54) ESD protection device, composite electronic component of the same, manufacturing method of composite substrate, and manufacturing method of ESD protection device

(75) Inventors: Kensaku Asakura, Tokyo (JP); Yasuhiro Hirobe, Tokyo (JP); Atsushi Hitomi, Tokyo (JP); Takeshi Urano, Tokyo (JP)

Correspondence Address: OLIFF & BERRIDGE, PLC, P.O. BOX 320850, ALEXANDRIA, VA, 22320-4850, US

(73) Assignee: TDK CORPORATION, Tokyo (JP)

(21) Appl. No.: 12/656,056

(22) Filed: Jan. 14, 2010

(30) Foreign Application Priority Data
Jan. 14, 2009 (JP) 2009-005986
Dec. 3, 2009 (JP) 2009-275715

(51) Int. Cl. H01L 23/60; H01L 23/52; H01L 21/768

(52) U.S. Cl. 257/531; 257/773; 438/666; 361/56; 257/E23.141; 257/E21.576

(57) ABSTRACT

The present invention provides an ESD protection device and the like having improved durability against repeated use. The ESD protection device includes a base 2 having an insulating surface 2a, electrodes 3a and 3b disposed on the insulating surface 2a and facing but spaced apart from each other, and a functional layer 4 disposed on at least between the electrodes 3a and 3b, wherein composite in which particles of a conductive inorganic material 4b having an average particle diameter of 1 to 200 nm are discretely interspersed in a matrix of an insulating inorganic material 4a is adopted as the functional layer 4.

### BACKGROUND OF THE INVENTION

1. Field of the Invention

The present invention relates to an ESD protection device and a composite electronic component thereof, a manufacturing method of a composite substrate usable therefor, and a manufacturing method of the ESD protection device, and in particular, to an ESD protection device which is useful in a high-speed transmission system and which can advantageously be combined with a common mode filter.

2. Description of the Related Art

In recent years, size reduction and performance improvement of electronic apparatuses have been rapidly in progress. Furthermore, much effort has been made to increase transmission speed (an increased frequency exceeding 1 GHz) and to reduce driving voltage as typically seen in high-speed transmission systems such as USB2.0, S-ATA2, and HDMI. On the other hand, the withstand voltage of electronic components used in electronic apparatuses decreases consistently with the size reduction of electronic apparatuses and the reduced driving voltage therefor. Thus, it has been important to protect electronic components from overvoltage typified by electrostatic pulses generated when a human body comes into contact with a terminal of an electronic apparatus.

In order to protect electronic components from such electrostatic pulses, a method of providing a barrister or the like between the ground and a line to be subjected to static electricity has generally been used, and a method of adopting a surge absorber including long-lasting electrodes has been proposed (see Patent Documents 1 to 3). However, the use, in a high-speed transmission system, of the barrister or the like, which has a large electrostatic capacitance, not only increases a discharge starting voltage but also degrades signal quality.

On the other hand, an antistatic component with a low electrostatic capacitance has been proposed which includes an electrostatic protection material filled between opposite electrodes. For example, Patent Document 4 discloses an antistatic component including an electrostatic protection material layer formed between a pair of electrodes by, in order to enhance an electrostatic inhibition effect, kneading metal particles with a passive layer formed on the surface thereof, a silicone-containing resin, and an organic solvent to obtain electrostatic protection material paste and applying the electrostatic protection material paste to between the opposite electrodes by screen printing before drying.

[Patent Document 1] Japanese Patent Laid-Open No. 2007-242404

[Patent Document 2] Japanese Patent Laid-Open No. 2002-015831

[Patent Document 3] Japanese Patent Laid-Open No. 2007-048759

[Patent Document 4] Japanese Patent Laid-Open No. 2007-265713

However, the antistatic component described in Patent Document 4 is low in the frequency of repeated use and is, therefore, inferior in durability.

The present invention has been made in view of the above circumstances. An object of the present invention is to provide an ESD protection device offering improved durability against repeated use, a composite electronic component combined with the ESD protection device, a manufacturing method of a composite substrate usable therefor, and a manufacturing method of the ESD protection device. Another object of the present invention is to provide an ESD protection device having excellent heat resistance and weather resistance, allowing a further reduction in the thickness thereof, being superior in productivity and economic efficiency, and a composite electronic component combined with the ESD protection device.

### SUMMARY OF THE INVENTION

To accomplish the above-described objects, the present inventors conducted earnest studies. The present inventors have thus found that in what is called a gap type ESD protection device including an electrostatic protection material (functional layer) filled between opposite electrodes, durability against repeated use can be improved by adopting a functional layer in which conductive inorganic materials smaller in average particle diameter than conventional ones are dispersed in a matrix of an insulating material. The present inventors have thus completed the present invention.

That is, the present invention provides an ESD protection device including a base having an insulating surface, electrodes disposed on the insulating surface and facing but spaced apart from each other, and a functional layer disposed on at least between the electrodes, wherein the functional layer is a composite in which conductive inorganic materials having an average particle diameter of 1 to 200 nm are discretely dispersed in a matrix of an insulating material.

In the specification, the term “composite” used herein means a state in which conductive inorganic materials are dispersed in a matrix of an insulating inorganic material, and includes a concept in which not only a state in which conductive inorganic materials are uniformly or randomly dispersed in a matrix of an insulating inorganic material, but also a state in which clusters (aggregates) of conductive inorganic materials are dispersed in a matrix of an insulating inorganic material, that is, a state typically called a sea-island structure. Furthermore, the term “insulating” used herein means that the resistivity is greater than or equal to 0.1 Ωcm, and the word “conductive” means that the resistivity is smaller than 0.1 Ωcm. What is called “semi-conductive” is included in the former word “insulating” as long as the specific resistivity of a material in question is greater than or equal to 0.1 Ωcm. Furthermore, the term “average particle diameter” means a value evaluated by a method of observation in later-described embodiments (an ESD protection device is polished from above a surface on which opposite electrodes are present and a microstructure is observed and imaged using an SEM or a TEM. Image processing is performed on the image thus taken, and the maximum diameter of particles of a conductive inorganic material is defined as a particle diameter. 1,000 particles in the image are sampled and the diameter of each particle is measured by means of similar processing. An average of the diameters of the 1,000 particles thus obtained is defined as an average particle diameter). Note that the conductive inorganic materials can disperse into the insulating matrix as particles 20 nm or less in diameter (primary particles) or as an aggregate (secondary particles) in which primary particles are combined with one another or aggregated. Here, an aggregate in which primary particles are in contact with one another is also regarded as one particle, that is, particle diameters are measured by including the maximum diameter of secondary particles. Furthermore, the term “durability” means performance evaluated based on the number of discharges occurring when electrostatic discharge tests are repeated in embodiments described below.

As a result of measurement of the characteristics of the ESD protection devices configured as described above, the present inventors have found that, compared to the conventional antistatic elements, the ESD protection devices have improved durability. The detail of the mechanism of this effect has not been clarified yet. However, for example, the mechanism can be assumed to be as follows.

In this kind of gap type ESD protection devices using a functional layer (electrostatic absorption material) in which metal particles are dispersed into an insulating matrix, discharge typically occurs in a conduction path in which the resistivity between the electrodes arranged opposite each other exhibits the smallest value. If such discharge occurs, particularly in the case of high-voltage discharge, part of an electrode in the path where the discharge has occurred and part of the functional layer may be damaged. Accordingly, the next discharge is thought to occur in a path different from this damaged path. In contrast, an ESD protection device having the above-described configuration adopts a functional layer which is a composite in which conductive inorganic materials having an average particle diameter of 1 to 200 nm are discretely dispersed in a matrix of an insulating material. The number of particles of the conductive inorganic material which the functional layer contains is therefore larger (under the same condition with regard to the amount of conductive inorganic material filled (volumetric ratio)), compared with conventional antistatic components. Consequently, there are formed a larger number of conduction paths for discharge. Accordingly, static electricity can be absorbed a larger number of times, compared with conventional antistatic components. As a result, a significant improvement is made to durability against repeated use. However, the effects of the present invention are not limited to those described above.

The above-described insulating material is preferably an insulating inorganic material. Instead of the above-described conventional organic-inorganic composite film, an insulating inorganic material is thus adopted as an insulating material for constituting a matrix to significantly improve heat resistance and weather resistance against an external environment including temperature and humidity. Furthermore, such a composite can be formed by using a thin-film formation method for an inorganic material, such as a sputtering method or a deposition method. Thus, compared with the formation of an organic-inorganic composite film of approximately several ten micrometers by coating based on stencil printing or screen printing followed by drying or the like, the formation of the composite facilitates a reduction in film thickness and improves productivity and economic efficiency.

Furthermore, the insulating inorganic material is preferably at least one species selected from the group consisting of Al₂O₃, TiO₂, SiO₂, ZnO, In₂O₃, NiO, CoO, SnO₂, V₂O₅, CuO, MgO, ZrO₂, AlN, BN, and SiC. These metal oxides are superior in the insulating property, heat resistance, and weather resistance and thus functions effectively as a material forming the insulating matrix of the composite. As a result, the metal oxides can be formed into a high-performance ESD protection device that is superior in the discharge property, heat resistance, and weather resistance. Moreover, the metal oxides are inexpensively available, and the sputtering method is applicable to these metal oxides. Thus, the metal oxides serve to improve productivity and economic efficiency.

Moreover, the above-described conductive inorganic material is preferably at least one species of metal selected from the group consisting of C, Ni, Cu, Au, Ag, Pd, Ti, Cr, and Pt, or a metal compound thereof. By blending any of the metals or metal compounds in a matrix of an insulating inorganic material so that the metal or metal compound is discretely dispersed, a high-performance ESD protection device is obtained which is superior in the discharge property, heat resistance, and weather resistance.

Another aspect of the present invention provides a composite electronic component effectively combined with the ESD protection device according to the present invention and including an inductor device and the ESD protection device that are provided between two magnetic bases, wherein the inductor device comprises an insulating layer composed of resin, and a conductor pattern formed on the insulating layer, and the ESD protection device comprises an underlying insulating layer formed on the magnetic base, electrodes disposed on the underlying insulating film and facing but spaced apart from each other, and a functional layer disposed on at least between the electrodes, wherein the functional layer is a composite in which conductive inorganic materials having an average particle diameter of 1 to 200 nm are discretely dispersed in a matrix of an insulating material.

Moreover, yet another aspect of the present invention provides a composite electronic component effectively combined with the ESD protection device according to the present invention and including a common mode filter layer and an ESD protection device layer that are provided between two magnetic bases, wherein the common mode filter layer comprises a first insulating layer and a second insulating layer both composed of resin, a first spiral conductor formed on the first insulating layer, and a second spiral conductor formed on the second insulating layer, and the ESD protection device layer comprises a first ESD protection device connected to one end of the first spiral conductor and a second ESD protection device connected to one end of the second spiral conductor, and wherein the first and second spiral conductors are formed on respective planes perpendicular to a stacking direction and arranged so as to be magnetically coupled together, and each of the first and second ESD protection devices includes an underlying insulating layer formed on the magnetic base, electrodes disposed on the underlying insulating layer and facing but spaced apart from each other, and a functional layer disposed on at least between the electrodes, and wherein the functional layer is a composite in which conductive inorganic materials having an average particle diameter of 1 to 200 nm are discretely dispersed in a matrix of an insulating material.

Moreover, still another aspect of the present invention provides a preferred manufacturing method of a composite substrate usable for the ESD protection device of the present invention, the method including the steps of preparing a stack provided with electrodes disposed on an insulating surface of a base and facing but spaced apart from each other, and applying a conductive inorganic material to a gap between the electrodes using a sputtering method, thereby forming a first layer in which the conductive inorganic materials having an average particle diameter of 1 to 200 nm are discretely distributed.

Moreover, still another aspect of the present invention provides a preferred manufacturing method of the ESD protection device according to the present invention, the method including the steps of preparing a stack provided with electrodes disposed on an insulating surface of a base and facing but spaced apart from each other, applying a conductive inorganic material to a gap between the electrodes using a sputtering method, thereby forming a first layer in which the conductive inorganic materials having an average particle diameter of 1 to 200 nm are discretely distributed, and further applying an insulating material onto the first layer using a sputtering method, thereby forming a composite in which the conductive inorganic materials having an average particle diameter of 1 to 200 nm are discretely dispersed in a matrix of the insulating material.

The present invention provides an ESD protection device with improved durability against repeated use and a composite electronic component combined with the ESD protection device. Moreover, the present invention allows the heat resistance to be improved and enables films in the device and component to be further thinned, compared with the related art. As a result, the present invention can improve productivity and economic efficiency. Furthermore, the present invention provides a manufacturing method by which an ESD protection device usable for the device and component can be manufactured in a simple and convenient manner and with excellent reproducibility.

### BRIEF DESCRIPTION OF THE DRAWINGS

FIG. 1 is a schematic sectional view schematically showing an ESD protection device 1;

FIG. 2 is a schematic plan view of a functional layer 4 in the ESD protection device 1;

FIG. 3 is a schematic sectional view schematically showing an ESD protection device 6;

FIG. 4 is a schematic perspective view showing the external configuration of a composite electronic component 100;

FIG. 5 is a circuit diagram showing the configuration of the composite electronic component 100;

FIG. 6 is a schematic exploded perspective view showing an example of the layer structure of the composite electronic component 100;

FIG. 7 is a schematic plan view showing the positional relationship between gap electrodes 28 and 29 and other conductive patterns;

FIG. 8 is a view showing an example of a layer structure near the first gap electrode 28 in an ESD protection device layer 12b, wherein FIG. 8(a) is a schematic plan view and FIG. 8(b) is a schematic sectional view;

FIG. 9 is a schematic perspective view showing a process of manufacturing the ESD protection device 1;

FIG. 10 is a schematic perspective view showing the process of manufacturing the ESD protection device 1;

FIG. 11 is a schematic perspective view showing the process of manufacturing the ESD protection device 1; and

FIG. 12 is a circuit diagram for electrostatic discharge tests.

### DETAILED DESCRIPTION OF THE EMBODIMENTS

Embodiments of the present invention will be described below. Positional relationships such as vertical and lateral positions are based on those shown in the drawings unless otherwise specified. Moreover, dimensional scales for the drawings are not limited to those shown in the drawings. Furthermore, the embodiments described below are examples based on which the present invention will be described. The present invention is not limited to the embodiments.

### First Embodiment

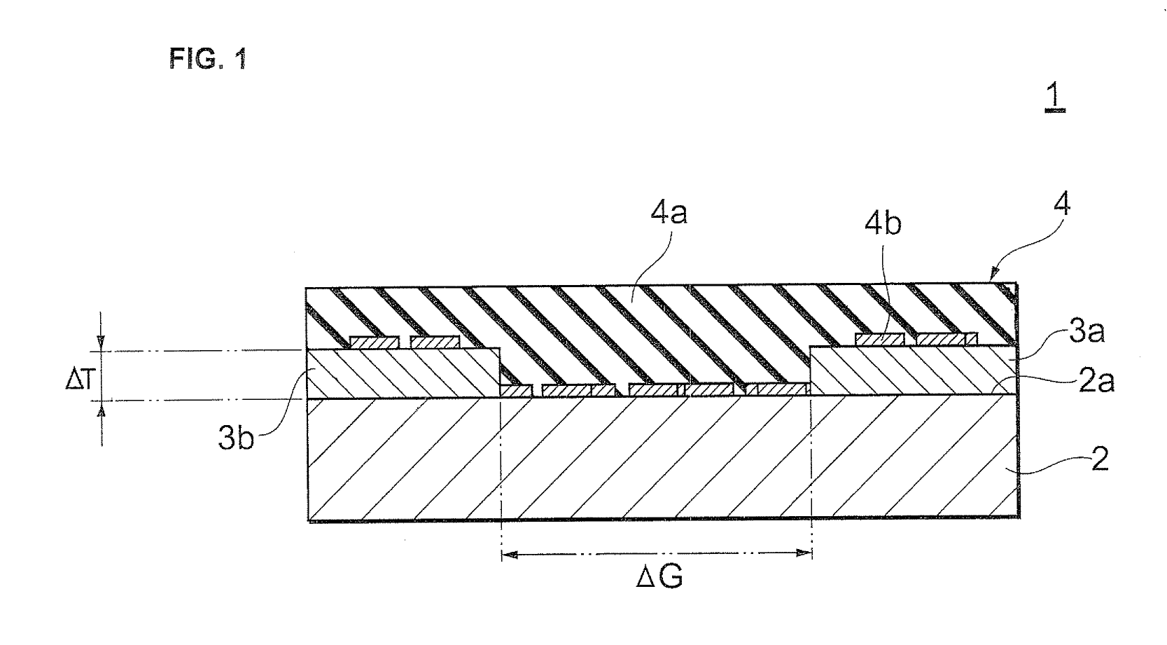

FIG. 1 is a schematic sectional view schematically showing a preferred embodiment of an ESD protection device according to the present invention. An ESD protection device 1 includes a base 2 having an insulating surface 2a, paired electrodes 3a and 3b disposed on the insulating surface 2a, a functional layer 4 disposed between the electrodes 3a and 3b, and a terminal electrode 5 (not shown in the drawings) electrically connected to the electrodes 3a and 3b. In the ESD protection device 1, the functional layer 4 is designed to function as an electrostatic protection material of a low voltage discharge type, so that when overvoltage such as static electricity is applied to the ESD protection device 1, initial discharge occurs between the electrodes 3a and 3b via the functional layer 4.

The base 2 has the insulating surface 2a. Here, the base 2 having the insulating surface 2a is a concept including, besides a substrate comprised of an insulating material, a substrate with an insulating film produced on a part or the entirety of the substrate. The dimensions and shape of the base 2 are not particularly limited provided that the base 2 can support at least the electrodes 3a and 3b and the functional layer 4.

A specific example of the base 2 may include a ceramic substrate and a single-crystal substrate comprised of a low-dielectric-constant material with a dielectric constant of 50 or lower, preferably at 20 or lower, such as NiZn ferrite, alumina, silica, magnesia, and aluminum nitride. Other preferred example may include any of heretofore-known substrates with an insulating film formed on the surface thereof and comprised of a low-dielectric-constant material with a dielectric constant of at 50 or lower, preferably at 20 or lower, such as NiZn ferrite, alumina, silica, magnesia, and aluminum nitride. An applicable method for forming an insulating film is not particularly limited to a specific one, and may be a heretofore-known technique such as a vacuum deposition method, a reactive deposition method, a sputtering method, an ion plating method, or a gas phase method such as CVD or PVD. Furthermore, the thickness of the substrate and the insulating film can be set as appropriate.

The paired electrodes 3a and 3b are disposed on the insulating surface 2a of the base 2 away from each other. In the present embodiment, the paired electrodes 3a and 3b are oppositely arranged at a substantially central position as seen in a plan view, with a gap distance ΔG between the electrodes 3a and 3b.

Specific examples of a material forming the electrodes 3a and 3b may include for example, one species of metal selected from Ni, Cr, Al, Pd, Ti, Cu, Ag, Au, and Pt, or an alloy thereof. However, the present invention is not particularly limited to these materials. In the present embodiment, each of the electrodes 3a and 3b is formed to be rectangular as seen in a plan view. However, the shape of the electrode is not particularly limited but may be like comb teeth or a saw. A method for forming the electrodes 3a and 3b (method for forming a gap between the electrodes 3a and 3b) is not particularly limited but may be an appropriately selected heretofore-known one. Specific examples of the method include methods of pattern formation using a laser or ion beams or using photolithography.

In order to ensure low-voltage initial discharge and to inhibit possible short-circuiting between the electrodes 3a and 3b with easily-processability maintained during gap formation, the gap distance ΔG between the electrodes 3a and 3b is preferably set to the ranges of 0.5 to 10 μm, and more preferably the ranges of 0.7 to 8 μm. On the other hand, the thickness ΔT of the electrodes 3a and 3b is preferably set to the ranges of 0.1 to 1 μm from the viewpoint of preventing the breakdown of the electrodes 3a and 3b at the time of discharge and the variation of the interelectrode gap distance ΔG, thereby enhancing the durability of the electrodes. In the specification, the term “gap distance ΔG” means the shortest distance between the electrodes 3a and 3b.

The functional layer 4 is disposed between the electrodes 3a and 3b. In the present embodiment, the functional layer 4 is stacked on the insulating surface 2a of the base 2 and on the electrodes 3a and 3b. The dimensional shape and the position disposed of the functional layer 4 are not particularly limited as long as they are designed such that initial discharge occurs between the electrodes 3a and 3b via the functional layer 4 itself when overvoltage is applied to the device.

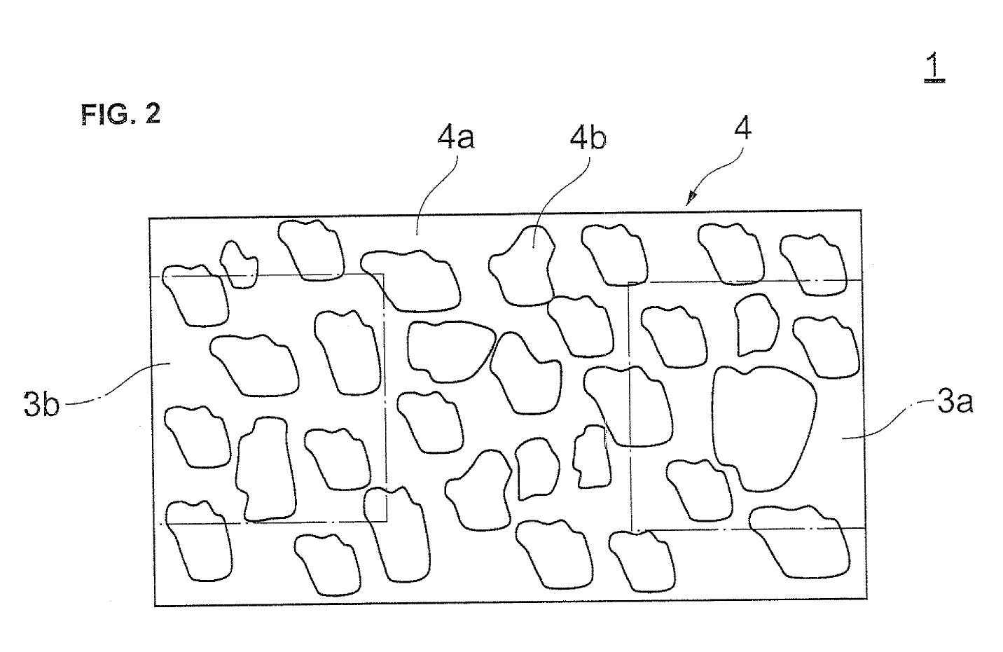

FIG. 2 is a schematic plan view of the functional layer 4.

The functional layer 4 is composed of a composite of a sea-island structure in which island-like agglomerates (particles) of conductive inorganic material 4b are discretely interspersed in a matrix of an insulating inorganic material 4a serving as an insulating material. In the present embodiment, the functional layer 4 is formed by sequential sputtering. More specifically, a layer of the conductive inorganic materials 4b is partially (incompletely) formed on the insulating surface 2a of the base 2 and/or the electrodes 3a and 3b by sputtering. Subsequently, the insulating inorganic material 4a is sputtered to form a composite of a stack structure comprised of the layer of the conductive inorganic materials 4b, the particles of which are interspersed like islands, and a layer of the insulating inorganic material 4a covering the layer of the conductive inorganic materials 4b.

Specific examples of the insulating inorganic material 4a forming the matrix include metal oxide and metal nitride. However, the present invention is not limited to these examples. In view of the insulating property and costs, preferable materials include Al₂O₃, TiO₂, SiO₂, ZnO, In₂O₃, SnO₂, NiO, CoO, V₂O₅, CuO, MgO, ZrO₂, AlN, BN, and SiC. One of these materials may be exclusively used or two or more of these materials may be used together. Among the materials, in view of a high insulating property applied to the insulating matrix, Al₂O₃, SiO₂, or the like is preferably used. On the other hand, in view of semi-conductivity applied to the insulating matrix, TiO₂ or ZnO is preferably used. By applying the semi-conductivity to the insulating matrix results in an ESD protection device allowing discharge to be started at a lower voltage. A method of applying the semi-conductivity to the insulating matrix is not particularly limited. For example, TiO₂ or ZnO may be used exclusively or together with any other insulating inorganic material 4a. In particular, during sputtering in an argon atmosphere, oxygen in TiO₂ is likely to be insufficient and electric conductivity tends to increase. Thus, TiO₂ is particularly preferably used in order to apply the semi-conductivity to the insulating matrix.

Specific examples of the conductive inorganic material 4b include metal, alloy, metal oxide, metal nitride, metal carbide, and metal boride. However, the present invention is not limited to these examples. In view of the conductivity, preferable materials include C, Ni, Cu, Au, Ti, Cr, Ag, Pd, and Pt or an alloy thereof.

The average particle diameter of the conductive inorganic materials 4b is required to be 1 to 200 nm, in order to significantly enhance durability against repeated use. Durability against repeated use tends to increase with a decrease in the average particle diameter of the conductive inorganic materials 4b. Conductive inorganic materials 4b having an average particle diameter smaller than 1 nm are difficult to form and are, therefore, remarkably inferior in productivity and economic efficiency. On the other hand, conductive inorganic materials 4b having an average particle diameter larger than 200 nm are inferior in durability against repeated use. Furthermore, since the number of places where particles of a conductive inorganic material 4b have contact with one another increases in a matrix, short-circuiting is likely to occur between the electrodes 3a and 3b. From these viewpoints, the average particle diameter of the conductive inorganic materials 4b is preferably 3 to 150 nm, and more preferably 5 to 100 nm.

The amount of the conductive inorganic materials 4b contained in the functional layer 4 is not particularly limited, but is preferably 0.1 to 80 vol %, and more preferably 0.5 to 60 vol %. Durability against repeated use tends to become higher as the content of the conductive inorganic materials 4b increases. On the other hand, this tends to cause short-circuiting between the electrodes 3a and 3b.

Preferred combinations of the insulating inorganic material 4a and the conductive inorganic material 4b include, but not particularly limited to, a combination of Cu and SiO₂ and a combination of Au and SiO₂. An ESD protection device comprised of these materials is not only superior in electrical characteristics but also advantageous in accurately and easily forming a composite of a sea-island structure in which island-like particles of the conductive inorganic materials 4b are discretely interspersed. Thus, the ESD protection device is extremely advantageous in terms of processability and cost-efficiency.

The total thickness of the functional layer 4 is not particularly limited but can be appropriately set. In order to allow a further reduction in film thickness to further reduce the size of an electronic apparatus using the ESD protection device 1 while improving the performance of the electronic apparatus, the total thickness is preferably set to the ranges of 10 nm to 10 μm, more preferably the ranges of 15 nm to 1 μM, and even more preferably the ranges of 15 to 500 nm. Furthermore, an extremely thin composite made of an inorganic material and having a thickness of the ranges of 10 nm to 1 μm can be formed by application of the well-known thin-film formation method such as the sputtering method or the deposition method. This improves the productivity of the ESD protection device 1, while reducing the costs thereof. When the layer of the discretely interspersed island-like conductive inorganic materials 4b and the layer of matrix of the insulating inorganic material 4a are formed as in the present embodiment, the thickness of the layer of the conductive inorganic materials 4b is preferably the ranges of 1 to 10 nm. The thickness of the layer of the insulating inorganic materials 4a is preferably the ranges of 10 nm to 10 μm, more preferably the ranges of 10 nm to 1 μm, and even more preferably the ranges of 10 to 500 nm.

A method for forming the functional layer 4 is not particularly limited, but any heretofore-known methods of thin-film formation can be applied. In addition to the above-described sputtering method, a deposition method or a printing method can be used to form the functional layer 4 by applying the insulating inorganic material 4a and the conductive inorganic material 4b onto the insulating surface 2a of the base 2 and/or the electrodes 3a and 3b. The sputtering method, among other methods, allows the functional layer 4 to be formed in a stable manner with excellent reproducibility. Furthermore, this method not only facilitates a further reduction in film thickness but also improves productivity and economic efficiency, compared with an organic-inorganic film formed using the above-described conventional printing method. The ESD protection device 1 according to the present embodiment may be configured so that application of a voltage between the electrodes 3a and 3b causes part of the electrodes 3a and 3b to disperse into the functional layer 4, resulting in the containment of the material forming the electrodes 3a and 3b in the functional layer 4.

In the ESD protection device 1 according to the present embodiment, the functional layer 4 containing the island-like conductive inorganic materials 4b discretely interspersed in the matrix of the insulating inorganic material 4a functions as an electrostatic protection material of a low-voltage discharge type. Specifically, when an electrostatic voltage is applied to between the paired electrodes 3a and 3b, discharge occurs in any paths formed by the island-like conductive inorganic materials 4b discretely interspersed in the matrix of the insulating inorganic material 4a, i.e., between points where energy concentrations are high. Electrostatic discharge energy is thus absorbed. High-voltage discharge may damage part of the electrodes or functional layer in a path where the discharge has occurred. Accordingly, the next discharge is thought to occur in a path different from this damaged path. However, the discretely interspersed island-like conductive inorganic materials 4b form a large number of current paths, thereby allowing static electricity to be absorbed a plural number of times.

In particular, as the functional layer 4, the ESD protection device 1 according to the present embodiment adopts a composite in which particles of the conductive inorganic material 4b having an average particle diameter of 1 to 200 nm are discretely interspersed like islands in the matrix of the insulating inorganic material 4a. Since there are formed a larger number of conduction paths for discharge, compared with conventional antistatic components, the ESD protection device has an extremely high level of durability against repeated use.

Furthermore, the present embodiment adopts the composite comprised at least of the insulating inorganic material 4a and the conductive inorganic material 4b, as the functional layer 4 functioning as an electrostatic protection material of a low-voltage discharge type. Thus, compared with the conventional antistatic element with the organic-inorganic composite film, the ESD protection device 1 is extremely superior in heat resistance and weather resistance. Moreover, since the functional layer 4 is formed by the sputtering method, the ESD protection device 1 serves to improve productivity and economic efficiency.

The ESD protection device 1 according to the first embodiment adopts, as the functional layer 4, the composite in which the conductive inorganic materials 4b are discretely dispersed in the matrix of the insulating inorganic material 4a. However, the functional layer 4 may be a composite in which metal particles, for example, Ag, Cu, Ni, Al, or Fe or particles of a conductive metal compound are dispersed in high insulating resin, such as silicone resin or epoxy resin.

Alternatively, a composite in which particles of the conductive inorganic material 4b are uniformly distributed in the matrix of the insulating material 4a may be adopted as the functional layer 4. Such a composite can be obtained by sputtering a target containing the insulating inorganic material 4a and the conductive inorganic material 4b (or by simultaneously sputtering a target containing the insulating inorganic material 4a and a target containing the conductive inorganic material 4b) onto the insulating surface 2a of the base 2 and/or the electrodes 3a and 3b.

### Second Embodiment

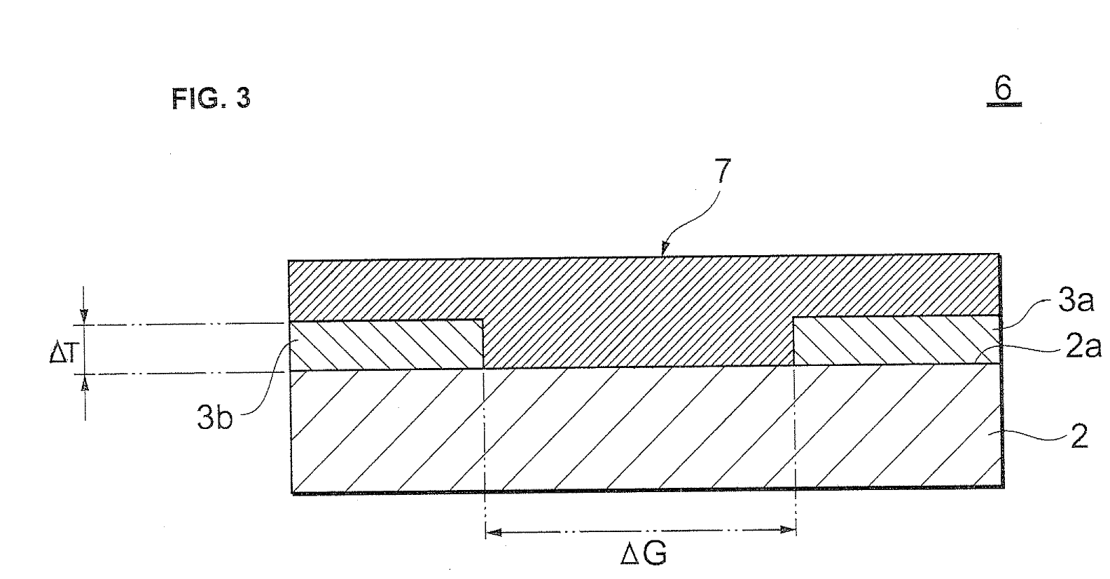

FIG. 3 is a schematic sectional view schematically showing another preferred embodiment of the ESD protection device according to the present invention. This ESD protection device 6 has the same configuration as that of the above-described ESD protection device 1 according to the first embodiment, except that the ESD protection device 6 has a functional layer 7 instead of the functional layer 4.

The functional layer 7 is a composite in which particles of a conductive inorganic material 4b (not shown in the drawings) are discretely dispersed in a matrix of an insulating inorganic material 4a (not shown in the drawings). In the present embodiment, the functional layer 7 is formed by sputtering (or simultaneously sputtering) a target containing the insulating inorganic material 4a (or a target containing the insulating inorganic material 4a and the conductive inorganic material 4b) onto an insulating surface 2a of a base 2 and/or electrodes 3a and 3b and then applying a voltage to between the electrodes 3a and 3b to allow part of the electrodes 3a and 3b to disperse randomly into the insulating inorganic material 4a. Thus, as the conductive inorganic material 4b, the functional layer 7 of the present embodiment contains at least a material forming the electrodes 3a and 3b.

The total thickness of the functional layer 7 is not particularly limited but can be appropriately set. However, in order to allow a further reduction in film thickness, the total thickness is preferably set to the ranges of 10 nm to 10 μm, more preferably the ranges of 10 nm to 1 μm, and even more preferably the ranges of 10 to 500 nm.

In the ESD protection device 6 according to the present embodiment, the composite in which the granular conductive inorganic materials 4b are discretely dispersed in the matrix of the insulating inorganic material 4a is adopted as the functional layer 7 functioning as an electrostatic protection material of a low-voltage discharge type. This configuration also exerts operational effects similar to those of the above-described first embodiment.

### Third Embodiment

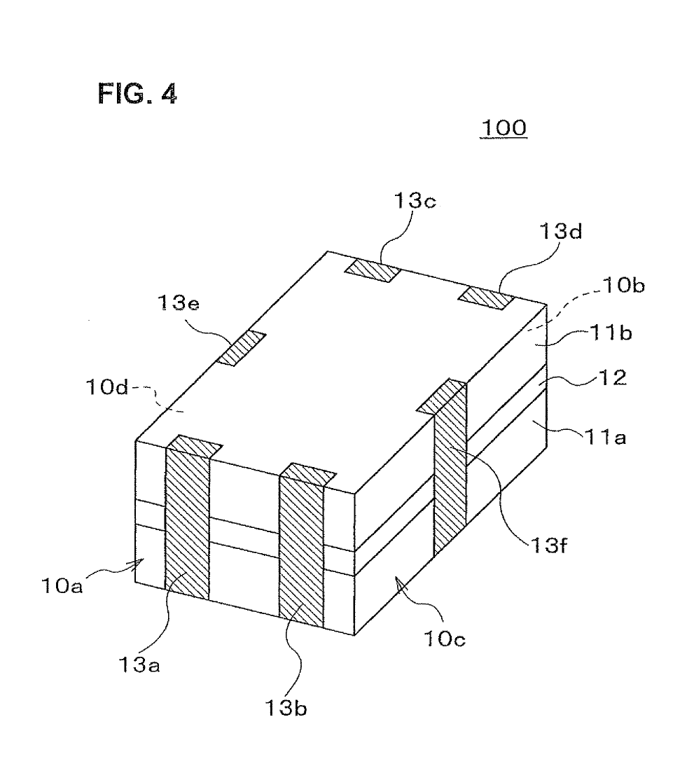

FIG. 4 is a perspective view schematically showing the external configuration of a preferred embodiment of a composite electronic component according to the present invention.

As shown in FIG. 4, a composite electronic component 100 according to the present embodiment is a thin-film common mode filter having an electrostatic protection function. The composite electronic component 100 includes a first magnetic base 11a and a second magnetic base 11b and a composite functional layer 12 sandwiched between the first magnetic base 11a and the second magnetic base 11b. Furthermore, a first terminal electrode 13a to a sixth terminal electrode 13f are formed on the outer peripheral surface of a stack composed of the first magnetic base 11a, the composite functional layer 12, and the second magnetic base 11b. The first and second terminal electrodes 13a and 13b are formed on a first side surface 10a. The third and fourth terminal electrodes 13c and 13d are formed on a second side surface 10b located opposite the first side surface 10a. The fifth terminal electrode 13e is formed on a third side surface 10c located orthogonally to the first and second side surfaces 10a and 10b. The sixth terminal electrode 13f is formed on a fourth side surface 10d located opposite the third side surface.

The first and second magnetic bases 11a and 11b physically protect the composite functional layer 12 and serves as a closed magnetic circuit for the common mode filter. Sintered ferrite, composite ferrite (a resin containing powdery ferrite), or the like can be used as a material for the first and second magnetic bases 11a and 11b.

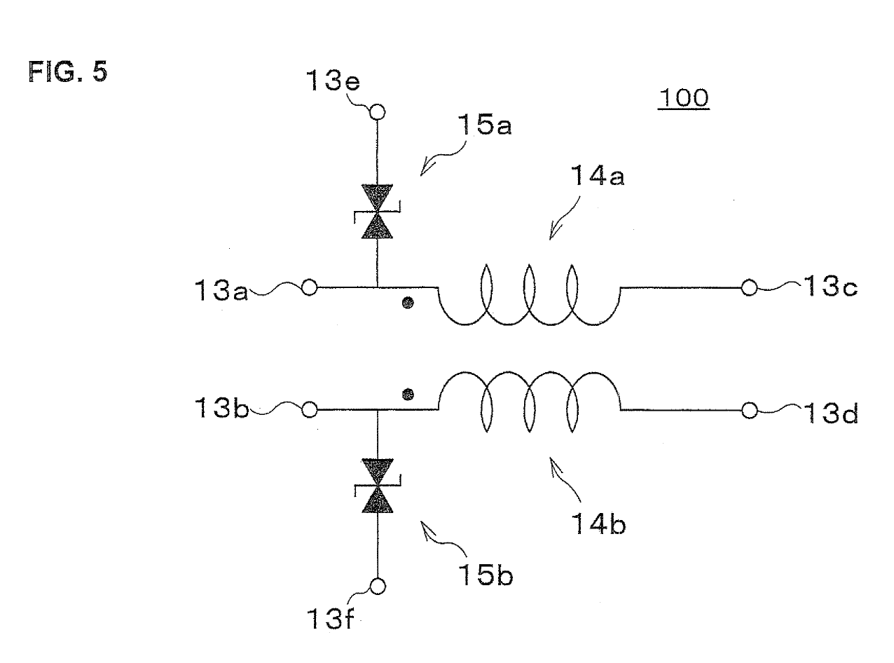

FIG. 5 is a circuit diagram showing the configuration of the composite electronic component 100.

As shown in FIG. 5, the composite electronic component 100 includes inductor devices 14a and 14b functioning as common mode choke coils, and ESD protection devices 15a and 15b. One end of the inductor device 14a is connected to the first terminal electrode 13a. One end of the inductor device 14b is connected to the second terminal electrode 13b. The other end of the inductor device 14a is connected to the third terminal electrode 13c. The other end of the inductor device 14b is connected to the fourth terminal electrode 13d. Furthermore, one end of an ESD protection device 15a is connected to the first terminal electrode 13a. One end of an ESD protection device 15b is connected to the second terminal electrode 13b. The other end of the ESD protection device 15a is connected to the fifth terminal electrode 13e. The other end of the ESD protection device 15b is connected to the sixth terminal electrode 13f. When the composite electronic component 100 is mounted on a pair of signal lines, the first and second terminal electrodes 13a and 13b are connected to the input sides of the respective signal lines. The third and fourth terminal electrodes 13c and 13d are connected to the output sides of the respective signal lines. Furthermore, the fifth and sixth terminal electrodes 13e and 13f are connected to a ground line.

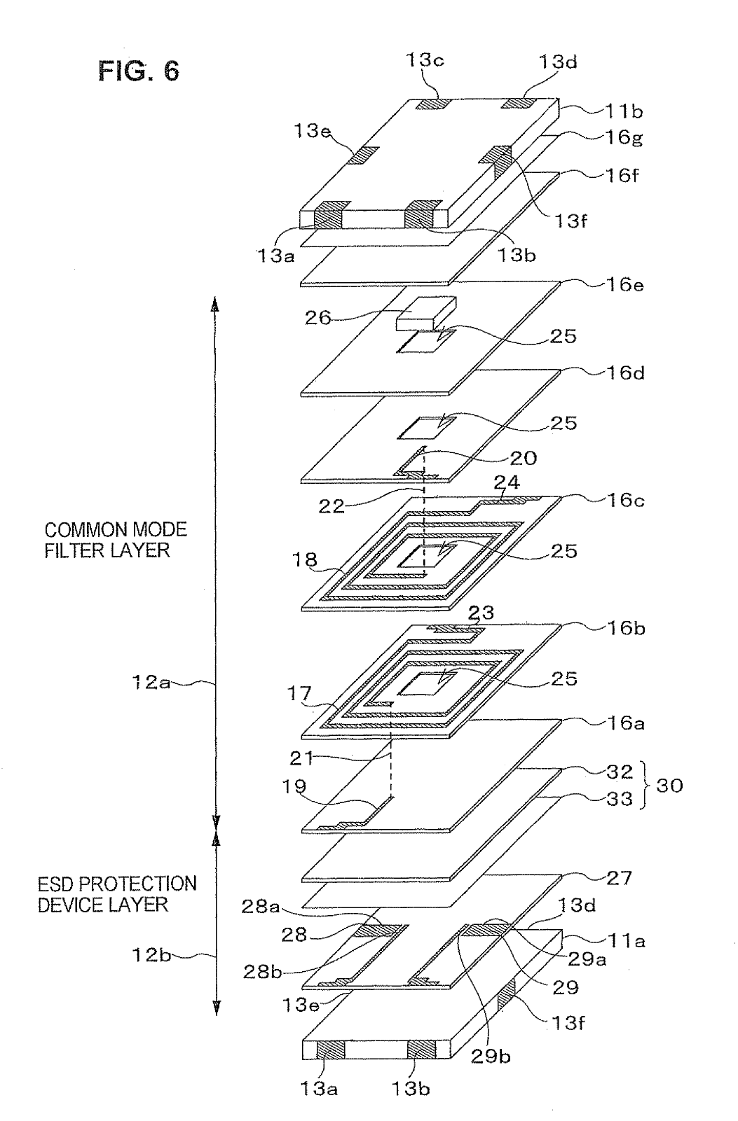

FIG. 6 is an exploded perspective view showing an example of the layer structure of the composite electronic component 100.

As shown in FIG. 6, the composite electronic component 100 includes a first magnetic base 11a and a second magnetic base 11b, and a composite functional layer 12 sandwiched between the first and second magnetic bases 11a and 11b. The composite functional layer 12 is composed of a common mode filter layer 12a and an ESD protection device layer 12b.

The common mode filter layer 12a includes insulating layers 16a to 16e, a magnetic layer 16f, an adhesive layer 16g, a first spiral conductor 17 formed on the insulating layer 16b, a second spiral conductor 18 formed on the insulating layer 16c, a first extraction conductor 19 formed on the insulating layer 16a, and a second extraction conductor 20 formed on the insulating layer 16d.

The insulating layers 16a to 16e insulate conductor patterns from one another or each of the conductor patterns from the magnetic layer 16f. The insulating layers 16a to 16e also serve to maintain the planarity of the underlying surface on which each conductor pattern is formed. A preferable material for the insulating layers 16a to 16e is a resin offering superior electric and magnetic insulating properties as well as excellent processability. That is, the preferable material is a polyimide resin or an epoxy resin. As the conductive patterns, Cu, Al, or the like, which is superior in conductivity and processability, is preferably used. The conductor patterns can be formed by an etching method or an additive method (plating) using photolithography.

An opening 25 penetrating the insulating layers 16a to 16e is formed in a central area of each of the insulating layers 16a to 16e and inside the first and second spiral conductors 17 and 18. The interior of the opening 25 is filled with a magnetic substance 26 forming a closed magnetic circuit between the first magnetic base 11a and the second magnetic base 11b. Composite ferrite or the like is preferably used as the magnetic substance 26.

Moreover, the magnetic layer 16f is formed on the surface of the insulating layer 16e. The magnetic substance 26 in the opening 25 is formed by hardening pasted composite ferrite (a resin containing magnetic powder). However, during hardening, the resin contracts to create recesses and protrusions in the opening portion. To allow the number of recesses and protrusions to be reduced as much as possible, the paste is preferably applied not only to the interior of the opening 25 but also to the entire surface of the insulating layer 16e. The magnetic layer 16f is formed in order to ensure such planarity of the magnetic layer 16f.

The adhesive layer 16g is necessary in order to stick the magnetic base 11b onto the magnetic layer 16f. The adhesive layer 16g also serves to reduce the recesses and protrusions on the surfaces of the magnetic base 11b and the magnetic layer 16f to allow tighter contact. A material for the adhesive layer 16g is not particularly limited but may be an epoxy resin, a polyimide resin, a polyamide resin, or the like.

The first spiral conductor 17 corresponds to the inductor device 14a shown in FIG. 5. The inner peripheral end of the first spiral conductor 17 is connected to the first terminal electrode 13a via a first contact hole conductor 21 penetrating the insulating layer 16b and the first extraction conductor 19. Furthermore, the outer peripheral end of the first spiral conductor 17 is connected to the third terminal electrode 13c via a third extraction conductor 23.

The second spiral conductor 18 corresponds to the inductor device 14b shown in FIG. 5. The inner peripheral end of the second spiral conductor 18 is connected to the second terminal electrode 13b via a second contact hole conductor 22 penetrating the insulating layer 16d and the second extraction conductor 20. Furthermore, the outer peripheral end of the second spiral conductor 18 is connected to the fourth terminal electrode 13d via a fourth extraction conductor 24.

Both the first and second spiral conductors 17 and 18 have the same planar shape and are provided at the same position as seen in a plan view. The first and second spiral conductors 17 and 18 perfectly overlap with each other and, therefore, strong magnetic coupling is present therebetween. With the above-described configuration, the conductor patterns in the common mode filter layer 12a form a common mode filter.

The ESD protection device layer 12b includes an underlying insulating layer 27, a first gap electrode 28 and a second gap electrode 29 formed on the surface of the underlying insulating layer 27, and an electrostatic absorption layer 30 covering the first and second gap electrodes 28 and 29. A layer structure near the first gap electrode 28 functions as the first ESD protection device 15a shown in FIG. 5. A layer structure near the second gap electrode 29 functions as the second ESD protection device 15b shown in FIG. 5. One end of the first gap electrode 28 is connected to the first terminal electrode 13a. The other end of the first gap electrode 28 is connected to the fifth terminal electrode 13e. Furthermore, one end of the second gap electrode 29 is connected to the second terminal electrode 13b. The other end of the second gap electrode 29 is connected to the sixth terminal electrode 13f.

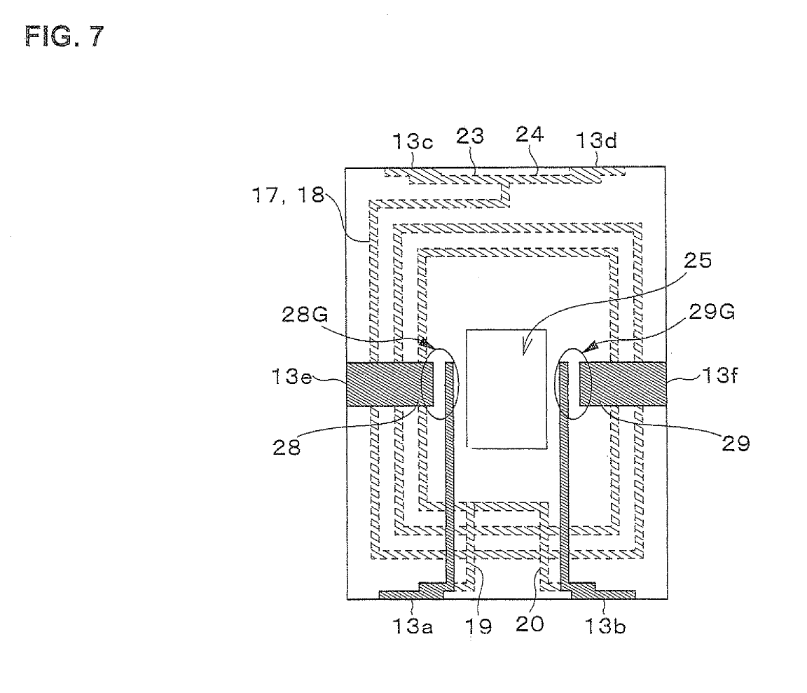

FIG. 7 is a schematic plan view showing the positional relationship between the gap electrodes 28 and 29 and the other conductor patterns.

As shown in FIG. 7, gaps 28G and 29G of the gap electrodes 28 and 29 are set at positions where the gap 28G and 29G two-dimensionally overlap with none of the first and second spiral conductors 17 and 18 and first and second extraction conductors 19 and 20 constituting the common mode filter. Although not particularly limited, in the present embodiment, the gaps 28G and 29G are set in free spaces inside the spiral conductors 17 and 18 and between the opening 25 and the spiral conductors 17 and 18. As will be described in detail later, the ESD protection device may be partly damaged or deformed by electrostatic absorption. Thus, if any conductor patterns are located so as to overlap with the ESD protection device, the conductor patterns may also be damaged. However, since the gaps 28G and 29G of the ESD protection devices are set at the positions where the gaps 28G and 29G do not overlap with any conductor patterns, when any ESD protection device is electrostatically damaged, the overlying and underlying layers can be prevented from being affected. As a result, an even more reliable composite electronic component can be provided.

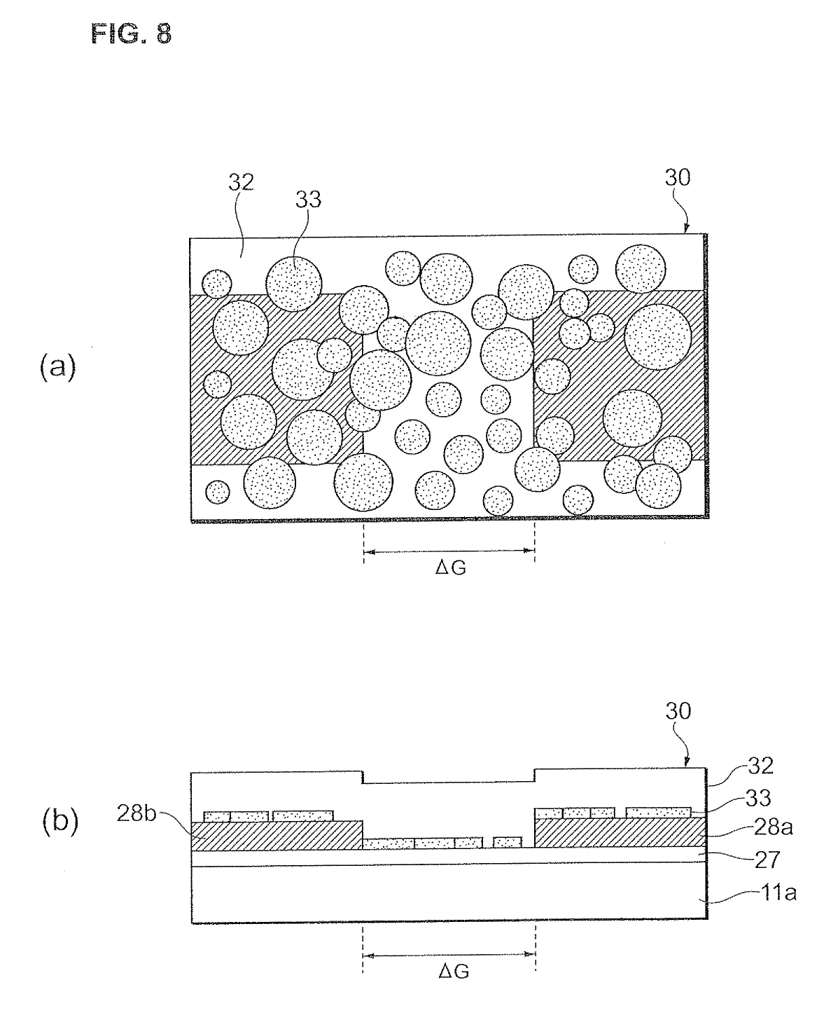

FIGS. 8A and 8B are views showing an example of the layer structure near the first gap electrode 28 in the ESD protection device layer 12b. FIG. 8A is a schematic plan view and FIG. 8B is a schematic sectional view. The configuration of the second gap electrode 29 is the same as that of the first gap electrode 28. Thus, duplicate descriptions are omitted.

The ESD protection device layer 12b includes an underlying insulating layer 27 formed on the surface of the magnetic base 11a, paired electrodes 28a and 28b constituting the first gap electrode 28, and an electrostatic absorption layer 30 disposed between the electrodes 28a and 28b.

The underlying insulating layer 27 functions as the insulating surface 2a in the above-described first embodiment, and is composed of an insulating material. In the present embodiment, the underlying insulating layer 27 covers the entire surface of the magnetic base 11a for reasons of ease of manufacture. However, the underlying insulating layer 27 has only to lie under at least the electrodes 28a and 28b and the electrostatic absorption layer 30 and need not necessarily cover the entire surface of the magnetic base 11a. Preferable specific examples of the underlying insulating layer 27 include not only a film formed of a low-dielectric-constant material with a dielectric constant of 50 or lower, preferably 20 or lower, such as NiZn ferrite, alumina, silica, magnesia, or aluminum nitride, but also an insulating film composed of any of these low-dielectric-constant materials and formed on any of various heretofore-known substrates. A method for producing the underlying insulating layer 27 is not particularly limited but may be a heretofore-known technique, such as a vacuum deposition method, a reactive deposition method, a sputtering method, an ion plating method, or a gas phase method such as CVD or PVD. Furthermore, the film thickness of the underlying insulating layer 27 can be appropriately set.

The electrodes 28a and 28b correspond to the electrodes 3a and 3b in the above-described first embodiment. Duplicate descriptions are thus omitted. Note that the gap distance ΔG between the electrodes 28a and 28b and the thickness ΔT of the electrode 28 are set according to the same relationship as that between the gap distance ΔG between the electrodes 3a and 3b and the thickness ΔT of the electrodes 3a and 3b in the above-described first embodiment.

The electrostatic absorption layer 30 is composed of a composite of a sea-island structure in which island-like aggregates of conductive inorganic material 33 are discretely interspersed in a matrix of an insulating inorganic material 32. The electrostatic absorption layer 30 corresponds to the functional layer 4 in the above-described first embodiment. Furthermore, the insulating inorganic material 32 and the conductive inorganic materials 33 correspond to the insulating inorganic material 4a and conductive inorganic materials 4b in the above-described first embodiment. Therefore, duplicate descriptions of these materials are omitted.

In the ESD protection device layer 12b, the electrostatic absorption layer 30 functions as an electrostatic protection material of a low voltage discharge type. The electrostatic absorption layer 30 is designed so that when overvoltage such as static electricity is applied to the component, initial (early) discharge occurs between the electrodes 28a and 28b via the electrostatic absorption layer 30. Furthermore, the insulating inorganic material 32 according to the present embodiment functions as a protection layer for protecting the paired electrodes 28a and 28b and the conductive inorganic materials 33 from any upper layer (for example, the insulating layer 16a).

As described above, the composite electronic component 100 according to the present embodiment contains an ESD protection device of a low voltage type offering a reduced electrostatic capacitance, a reduced discharge starting voltage, and improved durability against repeated use. Thus, the composite electronic component can function as a common mode filter having an advanced electrostatic protection function.

Furthermore, according to the present embodiment, the insulating inorganic material 32 and the conductive inorganic materials 33 are used as materials for the ESD protection device layer 12b, and none of the various materials forming the ESD protection device layer 12b contain resin. Thus, the ESD protection device layer 12b can be formed on the magnetic base 11a. Moreover, the common mode filter layer 12a can be formed on the ESD protection device layer 12b. A thermal treatment process at 350° C. or higher is required to form the common mode filter layer 12a using what is called a thin film formation method. A thermal treatment process at 800° C. is required to form the common mode filter layer 12a using what is called a stacking method of sequentially stacking ceramic sheets with respective conductive patterns formed thereon. If the insulating inorganic material 32 and the conductive inorganic material 33 are used for the ESD protection device layer, an ESD protection device which can function normally while withstanding the thermal treatment process can be reliably formed. Moreover, the ESD protection device can be formed on the sufficiently planar surface of the magnetic base. Thus, the fine gap of the gap electrode can be stably formed.

Additionally, according to the present embodiment, the gap electrodes are formed at the positions where the gap electrodes do not two-dimensionally overlap with the first and second spiral conductors and the like forming the common mode filter to avoid the conductor patterns thereof. This prevents possible vertical impacts when the ESD protection device is electrostatically damaged in part. Thus, a more reliable composite electronic component can be provided.

Moreover, according to the present embodiment, the composite electronic component 100 is mounted on the paired signal lines and the ESD protection devices 15a and 15b are provided closer to the input sides of the signal lines than the common mode filter, as shown in FIG. 5. This enables an increase in the efficiency with which the ESD protection device absorbs overvoltage. The electrostatic overvoltage is normally an abnormal voltage with impedance unmatched, and is thus reflected once at the input end of the common mode filter. The reflection signal is superimposed on the original signal waveform. The resulting signal with a raised voltage is absorbed by the ESD protection device at a time. That is, the common mode filter provided after the ESD protection device enlarges the waveform compared with the original one. The ESD protection device thus allows the overvoltage to be absorbed more easily than at a lower voltage level. Thus, the signal absorbed once is input to the common mode filter, which can then remove even faint noise.

### EXAMPLES

The present invention will be described below in detail with reference to examples. However, the present invention is not limited to the examples

### Example 1

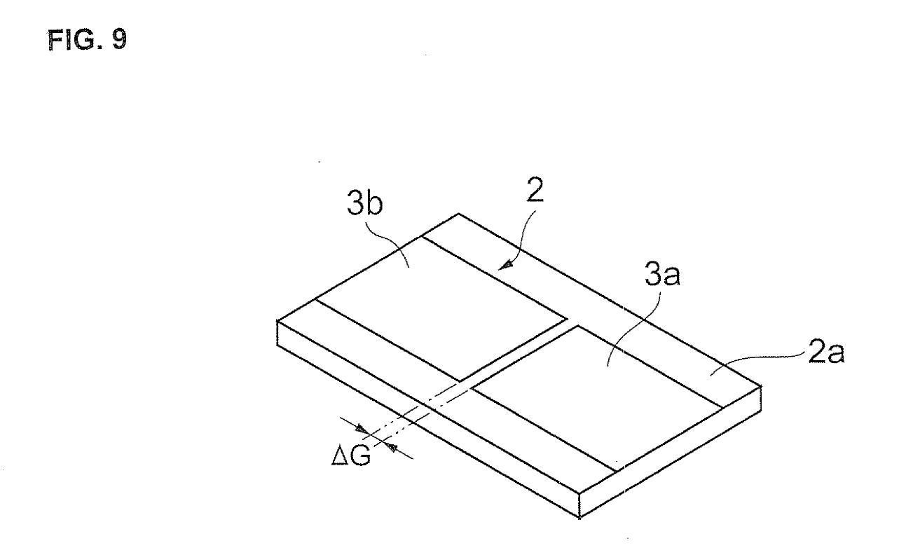

As shown in FIG. 9, first, on one insulating surface 2a of an insulating base 2 (an NiZn ferrite substrate; a dielectric constant: 13; manufactured by TDK Corporation; size: 1.6 mm×0.8 mm; thickness: 0.5 mm), a thin chromium film of length 1.6 mm, width 0.5 mm, and thickness 10 nm was pattern-formed as an underlying layer (tight contact layer) by the sputtering method using a mask. Then, a thin Cu film of thickness 0.1 μm was formed on this thin chromium film by a sputtering method using a mask, thereby forming a metal thin film having a two-layer structure composed of chromium and copper layers. Thereafter, milling processing based on ion beams was performed on the formed metal thin film to form gaps. Thus, paired band-like electrodes 3a and 3b arranged away from and opposite each other and the gaps were pattern-formed. Each of the electrodes 3a and 3b was sized so as to have a length of approximately 0.8 mm and a width of approximately 0.5 mm. The gap distance ΔG between the electrodes 3a and 3b was 1 μm.

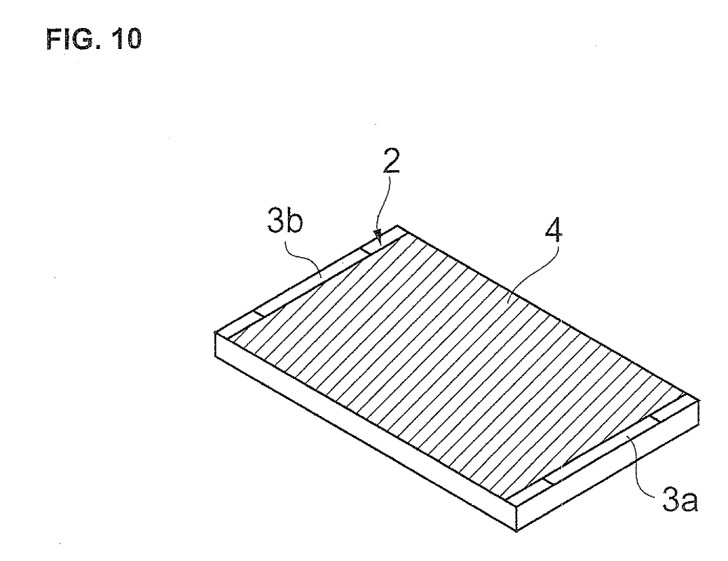

Then, as shown in FIG. 10, a functional layer 4 was formed on the insulating surface 2a of the base 2 and on the electrodes 3a and 3b according to the following procedure.

First, Au was partially deposited by sputtering on the surface of the base 2 on which the electrodes 3a and 3b were formed, to form a 20 nm-thick layer of a conductive inorganic material 4b in which Au particles were discretely interspersed like islands. This sputtering was carried out using a multi-target sputter apparatus (trade name: ES350SU; manufactured by EIKO Engineering Co., Ltd.) under the conditions of an argon pressure of 10 mTorr, an input power of 20 W, and a sputter time of 40 seconds. An SEM-based observation of microstructure of the layer of the conductive inorganic material 4b formed in this way verified that Au particles having an average particle diameter of 5 nm were discretely interspersed like islands. The average particle diameter was evaluated as an average value of 1000 particles sampled at random.

Then, silicon dioxide was deposited, by a sputtering method, almost all over the surface of the base 2 on which the electrodes 3a and 3b and the layer of the conductive inorganic material 4b were formed, so as to entirely cover the electrodes 3a and 3b and the layer of the conductive inorganic material 4b in the thickness direction. Thus, a 200 nm-thick layer of an insulating inorganic material 4a was formed. This sputtering was carried out using a multi-target sputter apparatus (trade name: ESU350; manufactured by EIKO Engineering Co., Ltd.) under the conditions of an argon pressure of 10 mTorr, an input power of 400 W, and a sputter time of 40 minutes.

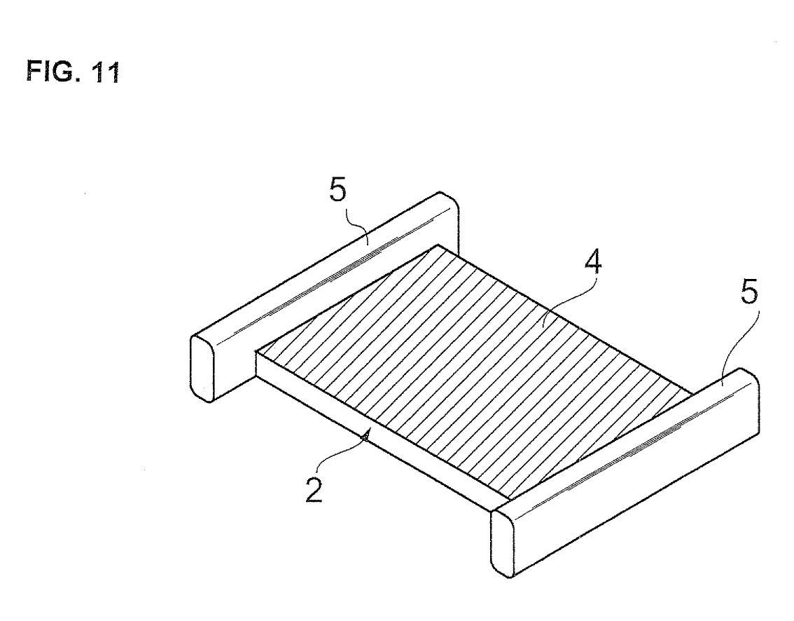

The above-described operations resulted in the formation of the functional layer 4 comprised of a composite in which particles of the conductive inorganic material 4b were discretely interspersed like islands in the matrix of the insulating inorganic material 4a. Thereafter, as shown in FIG. 11, terminal electrodes 5 composed mainly of Cu were formed, so as to connect to the outer peripheral ends of the electrodes 3a and 3b. As a result, an ESD protection device 1 of Example 1 was obtained.

### Example 2

Operations were performed in the same way as in Example 1, except that the sputtering conditions were changed (input power: 30 W, sputter time: 400 sec) to form a 20 nm-thick layer of the conductive inorganic material 4b in which Au particles were discretely interspersed like islands. Thus, an ESD protection device 1 of Example 2 was obtained. As with Example 1, SEM observation of the layer of the conductive inorganic material 4b verified that Au particles having an average particle diameter of 50 nm were discretely interspersed like islands.

### Example 3

Operations were performed in the same way as in Example 1, except that the sputtering conditions were changed (input power: 30 W, sputter time: 600 sec) to form a 50 nm-thick layer of the conductive inorganic material 4b in which Au particles were discretely interspersed like islands. Thus, an ESD protection device 1 of Example 3 was obtained. As with Example 1, SEM observation of the layer of the conductive inorganic material 4b verified that Au particles having an average particle diameter of 100 nm were discretely interspersed like islands.

### Example 4

Operations were performed in the same way as in Example 1, except that a composite (functional layer 7) in which particles of a conductive inorganic material were uniformly dispersed in an insulating resin was formed under the below-described conditions. Thus, an ESD protection device 1 of Example 4 was obtained. Weighing and kneading were performed so that Au particles 200 nm in diameter were mixed with a silicone resin at a predetermined volumetric ratio, thereby obtaining a paste-like mixture. This paste was coated onto electrodes by screen printing, and then heat-hardened at 150° C., thereby forming a functional layer in which metal particles were dispersed in an insulating matrix. As with Example 1, SEM observation of the functional layer 7 after the functional layer was cut in the thickness direction thereof verified that Au particles having an average particle diameter of 200 nm were discretely interspersed.

### Comparative Example 1

Operations were performed in the same way as in Example 1, except that a composite in which particles of a conductive inorganic material were uniformly dispersed in an insulating resin was formed under the below-described conditions. Thus, an ESD protection device of Comparative Example 1 was obtained. Weighing and kneading were performed so that Au particles 300 nm in diameter were mixed with a silicone resin at a predetermined volumetric ratio, thereby obtaining a paste-like mixture. This paste was coated onto electrodes by screen printing, and then heat-hardened at 150° C., thereby forming a functional layer in which metal particles were dispersed in an insulating matrix. As with Example 1, SEM observation of the functional layer 7 after the functional layer 7 was cut in the thickness direction thereof verified that Au particles having an average particle diameter of 300 nm were discretely interspersed like islands.

### Comparative Example 2

Operations were performed in the same way as in Example 1, except that a composite in which particles of a conductive inorganic material were uniformly dispersed in an insulating resin was formed under the below-described conditions. Thus, an ESD protection device of Comparative Example 2 was obtained. Weighing and kneading were performed so that Au particles 500 nm in diameter were mixed with a silicone resin at a predetermined volumetric ratio, thereby obtaining a paste-like mixture. This paste was coated onto electrodes by screen printing, and then heat-hardened at 150° C., thereby forming a functional layer in which metal particles were dispersed in an insulating matrix. As with Example 1, SEM observation of the functional layer after the functional layer was cut in the thickness direction thereof verified that Au particles having an average particle diameter of 500 nm were discretely interspersed.

### <Electrostatic Discharge Tests>

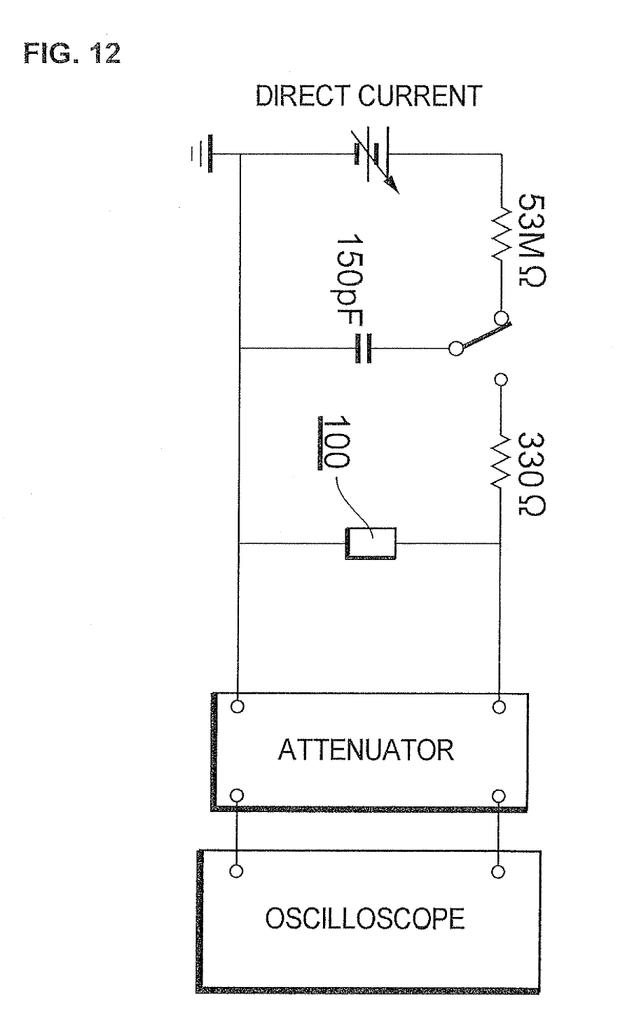

Then, an electrostatic test circuit shown in FIG. 12 was used to carry out electrostatic discharge tests on the ESD protection devices of Examples 1 to 4 and of Comparative Examples 1 and 2 obtained as described above.

The electrostatic discharge tests were carried out based on electrostatic discharge immunity tests and noise tests specified in the international standards IEC 61000-4-2, in conformity with the human body model (discharge resistance: 330 ohm; discharged capacity: 150 pF; applied voltage: 8 kV; contact discharge). Specifically, as shown in the electrostatic test circuit in FIG. 12, one terminal electrode of an ESD protection device to be evaluated was grounded. An electrostatic pulse application section was connected to the other terminal electrode of the ESD protection device. A discharge gun was brought into contact with the electrostatic pulse application section, so that electrostatic pulses were applied to the electrostatic pulse application section. The applied electrostatic pulses had a voltage equal to a discharge starting voltage or higher.

The discharge starting voltage is the voltage at which an electrostatic absorption effect is manifested in an electrostatic absorption waveform observed while a voltage of 0.4 kV is increased in 0.2-kV increments during static electricity tests. Furthermore, for discharge immunity, static electricity tests were repeated and the number of repetitions was counted until the ESD protection device stopped functioning. The discharge immunity was then evaluated based on the number of repetitions. Table 1 shows the results of the evaluation.

TABLE 1

| | Average particle | Volumetric | Gap | Device | Discharge starting | Discharge immunity |
|---|---|---|---|---|---|---|
| | diameter | ratio | distance | resistance | voltage | (number of |
| | (nm) | (vol %) | (μm) | (Ω) | (kV) | times) |
| Example 1 | 5 | 30 | 1 | 1.0E+09 | 1.2 | 200 |
| Example 2 | 50 | 30 | 1 | 1.0E+09 | 1.0 | 180 |
| Example 3 | 100 | 30 | 1 | 1.0E+09 | 1.0 | 180 |
| Example 4 | 200 | 30 | 1 | 1.0E+09 | 0.8 | 160 |
| Comparative | 300 | 30 | 1 | 1.0E+07 | 0.8 | 80 |
| Example 1 | | | | | | |
| Comparative | 500 | 30 | 1 | 1.0E+01 | Short- | 0 |
| Example 2 | | | | | circuited | |

As described above, the ESD protection device and the composite electronic component combined with the ESD protection device according to the present invention have improved durability against repeated use (discharge). Moreover, the ESD protection device and the composite electronic component offer a reduced discharge starting voltage, and improved heat resistance and weather resistance, and allow a further reduction in film thickness and an improvement in productivity and economic efficiency. The ESD protection device and the composite electronic component can be widely and effectively utilized for various electronic or electric devices and various apparatuses, facilities, systems, and the like including the electronic or electric devices. In particular, the ESD protection device and the composite electronic component can be widely and effectively utilized to prevent possible noise in high-speed differential transmission signal lines and video signal lines. Furthermore, methods for manufacturing the composite substrate and the ESD protection device according to the present invention can not only manufacture a composite substrate and an ESD protection device usable for such an ESD protection device and a composite electronic component as described above in a stable manner with excellent reproducibility but also improve productivity and economic efficiency. The methods can therefore be utilized widely and effectively in these fields.

1-8. (canceled)

9. An ESD protection device comprising:
a base having an insulating surface;
electrodes disposed on the insulating surface and facing but spaced apart from each other; and
a functional layer disposed on at least between the electrodes;
wherein the functional layer is a composite in which conductive inorganic materials having an average particle diameter of 1 to 200 nm are discretely dispersed in a matrix of an insulating material.

10. The ESD protection device according to claim 9,
wherein the insulating material is an insulating inorganic material.

11. The ESD protection device according to claim 10,
wherein the insulating inorganic material is at least one species selected from the group consisting of Al₂O₃, TiO₂, SiO₂, ZnO, In₂O₃, SnO₂, NiO, CoO, V₂O₅, CuO, MgO, ZrO₂, AlN, BN, and SiC.

12. The ESD protection device according to claim 9,
wherein the conductive inorganic material is at least one species of metal selected from the group consisting of C, Ni, Cu, Au, Ag, Pd, Ti, Cr, and Pt, or a metal compound thereof.

13. The ESD protection device according to claim 10,
wherein the conductive inorganic material is at least one species of metal selected from the group consisting of C, Ni, Cu, Au, Ag, Pd, Ti, Cr, and Pt, or a metal compound thereof.

14. The ESD protection device according to claim 11,
wherein the conductive inorganic material is at least one species of metal selected from the group consisting of C, Ni, Cu, Au, Ag, Pd, Ti, Cr, and Pt, or a metal compound thereof.

15. A composite electronic component comprising an inductor device and an ESD protection device that are provided between two magnetic bases,
wherein the inductor device comprises an insulating layer composed of resin, and a conductor pattern formed on the insulating layer, and
the ESD protection device comprises an underlying insulating layer formed on the magnetic base, electrodes disposed on the underlying insulating film and facing but spaced apart from each other, and a functional layer disposed on at least between the electrodes, and
wherein the functional layer is a composite in which conductive inorganic materials having an average particle diameter of 1 to 200 nm are discretely dispersed in a matrix of an insulating material.

16. A composite electronic component comprising a common mode filter layer and an ESD protection device layer that are provided between two magnetic bases, wherein
the common mode filter layer comprises:
a first insulating layer and a second insulating layer both composed of resin;
a first spiral conductor formed on the first insulating layer; and
a second spiral conductor formed on the second insulating layer;
and the ESD protection device layer comprises:
a first ESD protection device connected to one end of the first spiral conductor; and
a second ESD protection device connected to one end of the second spiral conductor; and
wherein the first and second spiral conductors are formed on respective planes perpendicular to a stacking direction and arranged so as to be magnetically coupled together, and
each of the first and second ESD protection devices includes an underlying insulating layer formed on the magnetic base, electrodes disposed on the underlying insulating layer and facing but spaced apart from each other, and a functional layer disposed on at least between the electrodes, and
wherein the functional layer is a composite in which conductive inorganic materials having an average particle diameter of 1 to 200 nm are discretely dispersed in a matrix of an insulating material.

17. A method for manufacturing a composite substrate, comprising the steps of:
preparing a stack provided with electrodes disposed on an insulating surface of a base and facing but spaced apart from each other; and
applying a conductive inorganic material to a gap between the electrodes using a sputtering method, thereby forming a first layer in which conductive inorganic materials having an average particle diameter of 1 to 200 nm are discretely distributed.

18. A method for manufacturing an ESD protection device, comprising the steps of:
preparing a stack provided with electrodes disposed on an insulating surface of a base and facing but spaced apart from each other;
applying a conductive inorganic material to a gap between the electrodes using a sputtering method, thereby forming a first layer in which the conductive inorganic materials having an average particle diameter of 1 to 200 nm are discretely distributed; and
further applying an insulating material onto the first layer using a sputtering method, thereby forming a composite in which the conductive inorganic materials having an average particle diameter of 1 to 200 nm are discretely dispersed in a matrix of the insulating material.
